(19) United States
(12) Patent Application Publication
(10) Pub. No.: US 2012/0090679 A1
(43) Pub. Date: Apr. 19, 2012

(54) METAL SUBSTRATE FOR A DYE SENSITIZED PHOTOVOLTAIC CELL

(75) Inventors: Kethinni G. Chittibabu, Westford, MA (US); Michael Graetzel, St-Sulpice (CH); David P. Waller, Lexington, MA (US); Srini Balasubramanian, Westford, MA (US); Kevin Coakley, Palo Alto, CA (US); Jin-An He, Parsippany, NJ (US); Jean Francois Penneau, Fontainebleau (FR); Igor Sokolik, East Boston, MA (US)

(73) Assignee: Konarka Technologies, Inc., Lowell, MA (US)

(21) Appl. No.: 13/257,172

(22) PCT Filed: Mar. 16, 2010
(86) PCT No.: PCT/US10/27483

§ 371 Date: Dec. 12, 2011

Related U.S. Application Data
(60) Provisional application No. 61/160,883, filed on Mar. 17, 2009.

(51) Int. Cl. H01L 31/0224

(52) U.S. Cl. 136/256

(57) ABSTRACT

Solid state dye sensitized photovoltaic cells, as well as related components, systems, and methods, are disclosed.

### CROSS REFERENCE TO RELATED APPLICATION

Pursuant to 35 U.S.C. §119(e), this application claims priority to U.S. Provisional Application Ser. No. 61/160,883, filed Mar. 17, 2009, the contents of which are hereby incorporated by reference.

### TECHNICAL FIELD

This disclosure relates to dye sensitized photovoltaic cells (e.g., hybrid or solid state dye sensitized photovoltaic cells), as well as related components, systems, and methods.

### BACKGROUND

Photovoltaic cells, sometimes called solar cells, can convert light, such as sunlight, into electrical energy. A typical photovoltaic cell includes a photovoltaically active material disposed between two electrodes. Generally, light passes through one or both of the electrodes to interact with the photovoltaically active material, which generates excited electrons that are eventually transferred to an external load in the form of electrical energy. One type of photovoltaic cell is a dye sensitized solar cell (DSSC).

### SUMMARY

In general, an inexpensive metal (e.g., an stainless steel, aluminum, or copper foil) is not suitable for use as the bottom electrode of a dye sensitized photovoltaic cell since such a metal typically forms an electrically insulating barrier on its surface in a high temperature sintering process used during the manufacture of a dye sensitized photovoltaic cell, which significantly reduces electric current that can be generated from the cell. In addition, such a metal could diffuse contaminants (e.g., metal ions) into the photoactive layer or hole blocking layer in a dye sensitized photovoltaic cell, thereby damaging the cell.

This disclosure is based on the discovery that an inexpensive metal (e.g., an stainless steel, aluminum, or copper foil) containing a thin coating (e.g., having a thickness of less than about 5 microns) of an electrically conductive material that either forms an n-type semiconductor metal oxide or forms no metal oxide during a high temperature sintering process can be effectively used as a bottom electrode in a dye sensitized photovoltaic cell. Such a metal foil can substantially reduce the manufacturing costs of a dye sensitized photovoltaic cell.

In one aspect, this disclosure features an article that includes a first electrode having first and second layers, a photoactive layer, and a second electrode. The first layer includes a first metal capable of forming an n-type semiconducting metal oxide. The second layer includes a second metal different from the first metal. The photoactive layer includes a first metal oxide and a dye, in which the first metal oxide is an n-type semiconducting metal oxide. The first layer is between the second layer and the photoactive layer. The photoactive layer is between the first layer and the second electrode. The article is configured as a solid state dye sensitized photovoltaic cell.

In another aspect, this disclosure features an article that includes a first electrode having first and second layers, a photoactive layer, and a second electrode. The first layer includes an electrically conductive material that does not form an electrically insulating metal oxide or a p-type semiconducting metal oxide upon heating at a temperature of about 500° C. in air. The second layer includes a metal. The photoactive layer includes a first metal oxide and a dye, in which the first metal oxide is an n-type semiconducting metal oxide. The first layer is between the second layer and the photoactive layer. The photoactive layer is between the first layer and the second electrode. The article is configured as a solid state dye sensitized photovoltaic cell.

In still another aspect, this disclosure features an article that includes a first electrode having first and second layers, a photoactive layer, a hole carrier layer, and a second electrode. The first layer includes an electrically conductive material that includes a first metal or a ceramic material. The first metal is selected from the group consisting of titanium, tantalum, niobium, zinc, tin, and an alloy thereof. The ceramic material includes titanium, tantalum, niobium, zinc, or tin. The second layer includes a second metal different from the first metal. The photoactive layer includes a titanium oxide and a dye, and includes a plurality of pores. A hole carrier material is disposed in at least some of the plurality of pores. The first layer is between the second layer and the photoactive layer. The photoactive layer is between the first layer and the hole carrier layer. The hole carrier layer includes the hole carrier material and is between the photoactive layer and the second electrode. The article is configured as a solid state dye sensitized photovoltaic cell.

Embodiments can include one or more of the following features.

The first metal can include titanium, tantalum, niobium, zinc, tin, or an alloy thereof.

The first layer can include titanium or titanium nitride.

The first layer can have a thickness of between about 100 nm and about 5 microns (e.g., between about 500 nm and about 2 microns).

The second metal can include iron, aluminum, copper, nickel, chromium, vanadium, manganese, tungsten, molybdenum, or an alloy thereof.

The second layer can have a thickness of between about 5 microns and about 500 microns.

The second layer can include a metal foil.

The first metal oxide can include a titanium oxide, a zinc oxide, a niobium oxide, a tantalum oxide, a tin oxide, a terbium oxide, or a mixture thereof.

The first metal oxide can include nanoparticles having an average particle diameter of between 20 nm and 100 nm.

The photoactive layer can be a porous layer. For example, the photoactive layer can include a plurality of pores. The photoactive layer can also include a hole carrier material in at least some of the plurality of pores.

The photovoltaic cell can further include a hole blocking layer between the first layer and the photoactive layer. The hole blocking layer can include a second metal oxide (e.g., an n-type semiconducting metal oxide). For example, the second metal oxide can include a titanium oxide, a zinc oxide, a niobium oxide, a tantalum oxide, a tin oxide, a terbium oxide, or a mixture thereof.

The hole blocking layer can have a thickness of between 5 nm and 50 nm.

The hole blocking layer can be a non-porous layer.

The photovoltaic cell can further include a hole carrier layer between the photoactive layer and the second electrode. The hole carrier layer can include a material selected from the group consisting of spiro-MeO-TAD, triaryl amines, polythiophenes, polyanilines, polycarbazoles, polyvinylcarbazoles, polyphenylenes, polyphenylvinylenes, polysilanes, polythienylenevinylenes, polyisothianaphthanenes, and copolymers or mixtures thereof. For example, the hole carrier layer can include spiro-MeO-TAD, poly(3-hexylthiophene), or poly(3,4-ethylenedioxythiophene).

The hole carrier layer can include a first hole carrier material, and the photoactive layer can include a plurality of pores and a second hole carrier material in at least some of the plurality of pores. The first hole carrier material can be the same as the second hole carrier material.

The second electrode can be transparent. For example, the second electrode can include a mesh or grid electrode.

The electrically conductive material in the first layer can be a material that does not form any metal oxide upon heating at a temperature of about 500° C. in air. The electrically conductive material can include a ceramic material containing titanium, tantalum, niobium, zinc, or tin. The ceramic material can include titanium nitride, titanium carbon nitride, titanium aluminum nitride, titanium aluminum carbon nitride, tantalum nitride, niobium nitride, zinc nitride, or tin nitride.

Embodiments can include one or more of the following advantages.

Without wishing to be bound by theory, it is believed that applying onto an inexpensive metal (e.g., a stainless steel, aluminum, or copper foil) a thin coating of an electrically conductive material that either forms an n-type semiconducting metal oxide or no metal oxide during a high temperature sintering process allow the inexpensive metal to be used as the main electrically conductive material in a bottom electrode, thereby maintaining the electrical conductivity of the bottom electrode while significantly reducing its manufacturing costs.

Other features, objects, and advantages of the invention will be apparent from the description, drawings, and claims.

### DESCRIPTION OF DRAWINGS

FIG. 1 is a cross-sectional view of a solid state dye sensitized photovoltaic cell.

FIG. 2 is a schematic of a system containing multiple photovoltaic cells electrically connected in series.

FIG. 3 is a schematic of a system containing multiple photovoltaic cells electrically connected in parallel.

Like reference symbols in the various drawings indicate like elements.

### DETAILED DESCRIPTION

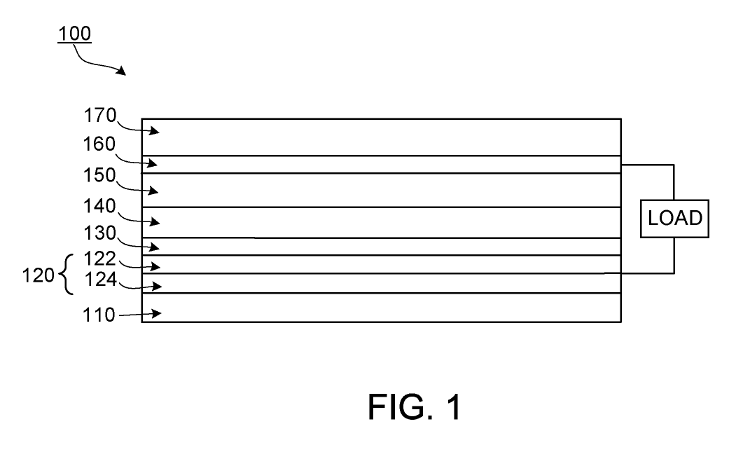

FIG. 1 shows a dye sensitized photovoltaic cell 100 having an optional substrate 110, a bottom electrode 120 having a first layer 122 and a second layer 124, an optional hole blocking layer 130, a photoactive layer 140, a hole carrier layer 150, a top electrode 160, an option substrate 170, an electrical connection between electrodes 120 and 160, and an external load electrically connected to photovoltaic cell 100 via electrodes 120 and 160. Photoactive layer 140 can include a semiconducting material (e.g., an n-type semiconducting metal oxide such as TiO₂ particles) and a dye associated with the semiconducting material. In some embodiments, photoactive layer 140 includes an inorganic semiconducting material (e.g., dye sensitized TiO₂) and hole carrier layer 150 includes an organic hole carrier material (e.g., poly(3-hexylthiophene) (P3HT) or poly(3,4-ethylenedioxythiophene) (PEDOT)). Such a photovoltaic cell is generally known as an organic-inorganic hybrid solar cell.

In general, when each layer in a photovoltaic cell is in a solid state (e.g., a solid film or layer), such a photovoltaic cell is referred to as a solid state photovoltaic cell. When a solid state photovoltaic cell contains a dye sensitized semiconducting material (e.g., a dye sensitized semiconducting metal oxide), such a photovoltaic cell is generally referred to as a solid state dye sensitized photovoltaic cell. In some embodiments, photovoltaic cell 100 is a solid state photovoltaic cell (e.g., a solid state dye sensitized photovoltaic cell).

Electrode 120 generally includes a first layer 122 and a second layer 124. In general, the first layer includes an electrically conductive material that does not form an electrically insulating barrier upon heating at a high temperature (e.g., about 450° C., about 475° C., about 500° C., about 525° C., or about 550° C.) in air. Examples of such an electrically insulating barrier include electrically insulating metal oxides (e.g., aluminum oxides) or p-type semiconducting metal oxides (e.g., copper oxides), which typically forms a schottky barrier (but not ohmic contact) with an n-type semiconducting material in a dye-sensitized solar cell. Examples of electrically conductive materials that do not from an electrically insulating barrier at a high temperature in air include an electrically conductive ceramic material or a metal that is capable of forming an n-type semiconducting metal oxide. Exemplary metals that form an n-type semiconducting metal oxide include titanium, tantalum, niobium, zinc, tin, or an alloy thereof. Exemplary electrically conductive ceramic materials include ceramic materials containing titanium, tantalum, niobium, zinc, or tin. For example, such ceramic materials can include titanium nitride, titanium carbon nitride, titanium aluminum nitride, titanium aluminum carbon nitride, tantalum nitride, niobium nitride, zinc nitride, or tin nitride. As an example, titanium nitride is a very stable ceramic material and generally does not form any metal oxide when heated below about 800° C. in air.

In some embodiment, first layer 122 includes an electrically conductive material that does not form any metal oxide upon heating at a high temperature (e.g., about 450° C., about 475° C., about 500° C., about 525° C., or about 550° C.) in air. Examples of such an electrically conductive material include an electrically conductive ceramic material, such as the ceramic materials described in the preceding paragraph.

When first layer 122 includes a metal (e.g., titanium) that is capable of forming an n-type semiconducting metal oxide (e.g., titanium oxide), the n-type semiconducting metal oxide can be formed in a high temperature sintering process used during the manufacture of a dye sensitized photovoltaic cell. Without wishing to be bound by theory, it is believed that such an n-type semiconducting metal oxide can form ohmic contact between photoactive layer 140 and electrode 120, which can facilitate electron transfer from photoactive layer 140 to electrode 120. In such embodiments, hole blocking layer 130 is optional and can be omitted from photovoltaic cell 100.

When first layer 122 includes an electrically conductive ceramic material (such as those described above), the ceramic material does not form any metal oxide in the high temperature sintering process during the manufacture of a dye sensitized photovoltaic cell. Without wishing to be bound by theory, it is believed that as the ceramic material is electrically conductive, it maintains sufficient electrical contact with photoactive layer 140 and therefore can facilitate electron transfer from photoactive layer 140 to electrode 120.

Without wishing to be bound by theory, it is believed that the n-type semiconducting metal oxide or the electrically conductive ceramic material in first layer 122 can prevent diffusion of contaminants (e.g., metal ions) from first layer 122 or second layer 124 to photoactive layer 140.

As the electrically conductive material used in first layer 122 (e.g., titanium or titanium nitride) is typically expensive, the thickness of first layer 122 should be sufficiently small to minimize manufacturing costs. On the other hand, the thickness of the first layer should be sufficiently large to provide adequate electrical conductivity. For example, first layer 122 can have a thickness of at most about 5 microns (e.g., at most about 4 microns, at most about 3 microns, at most about 2 microns, at most about 1 micron) or at least about 100 nm (at least about 200 nm, at least about 300 nm, at least about 400 nm, at least about 500 nm).

In general, second layer 124 can include any electrically conductive material. Preferably, second layer 124 can include an inexpensive metal (e.g., an inexpensive metal foil) to minimize manufacturing costs. Examples of suitable metals that can be used in second layer 124 include iron, aluminum, copper, nickel, chromium, vanadium, manganese, tungsten, molybdenum, or an alloy thereof. These metals generally are not suitable to be used as a bottom electrode in a dye sensitized photovoltaic cell by themselves as they form either an electrically insulating metal oxide (e.g., aluminum oxide) or a p-type semiconducting metal oxide (e.g., copper oxide) in the high temperature sintering process used during the manufacture of the dye sensitized photovoltaic cell. Without wishing to be bound by theory, it is believed that using first layer 122 described above in photovoltaic cell 100 allows use of an inexpensive metal (e.g., a stainless steel, aluminum, or copper foil) as the main electrically conductive material in a bottom electrode, thereby maintaining the electrical conductivity of the bottom electrode while significantly reducing its manufacturing costs.

The thickness of second layer 124 can vary as desired. In general, the thickness of second layer 124 should be sufficiently large to provide adequate electrically conductivity, but not overly large to minimize manufacturing costs. For example, second layer 124 can have a thickness of at least about 5 microns (e.g., at least about 10 microns, at least about 10 microns, at least about 50 microns, or at least about 100 microns) or at most about 500 microns (e.g., at most about 400 microns, at most about 300 microns, at most about 200 microns, at most about 100 microns).

In some embodiments, second layer 124 has a sufficiently large thickness such that it can provide adequate mechanical support to the entire photovoltaic cell 100. In such embodiments, substrate 110 is optional and can be omitted from photovoltaic cell 100. In certain embodiments, photovoltaic cell 100 can include an electrically insulating layer (not shown in FIG. 1) between first layer 122 and second layer 124. In such embodiments, second layer 124 functions solely as a substrate to provide mechanical support to photovoltaic cell 100 and does not function as an electrode.

Electrode 120 can be either transparent or non-transparent. As referred to herein, a transparent material is a material which, at the thickness used in a photovoltaic cell 100, transmits at least about 60% (e.g., at least about 70%, at least about 75%, at least about 80%, at least about 85%) of incident light at a wavelength or a range of wavelengths used during operation of the photovoltaic cell.

Electrode 120 can be made by the methods described herein or the methods known in the art. For example, second layer 124 can be a metal foil, which can be purchased from a commercial source. First layer 122 can be coated onto second layer 124 by a gas phase-based coating process, such as chemical or physical vapor deposition processes. As an example, titanium can be coated onto second layer 124 by using a physical vapor deposition process (e.g., by sputtering) to form first layer 122. As another example, titanium nitride can be coated onto second layer 124 by using either a physical vapor deposition process (e.g., by sputtering) or a chemical vapor deposition (e.g., by vaporizing titanium and reacting it with nitrogen in a high energy, vacuum environment) to form first layer 122.

Turning to other components, photovoltaic cell 100 can include an optional substrate 110, which can be formed of either a transparent or non-transparent material. Exemplary materials from which substrate 110 can be formed include polymers such as polyethylene terephthalates, polyimides, polyethylene naphthalates, polymeric hydrocarbons, cellulosic polymers, polycarbonates, polyamides, polyethers, and polyether ketones. In certain embodiments, substrate 110 can be formed of a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 megaPascals (e.g., less than about 1,000 megaPascals or less than about 5,00 megaPascals). In certain embodiments, different regions of substrate 110 can be flexible, semi-rigid, or inflexible (e.g., one or more regions flexible and one or more different regions semi-rigid, one or more regions flexible and one or more different regions inflexible).

Typically, substrate 110 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Optionally, photovoltaic cell 100 can include a hole blocking layer 130. The hole blocking layer is generally formed of a material that, at the thickness used in photovoltaic cell 100, transports electrons to electrode 120 and substantially blocks the transport of holes to electrode 120. Examples of materials from which the hole blocking layer can be formed include LiF, metal oxides (e.g., zinc oxide, titanium oxide), and amines (e.g., primary, secondary, or tertiary amines). Examples of amines suitable for use in a hole blocking layer have been described, for example, in commonly-owned co-pending U.S. Application Publication No. 2008-0264488, the entire contents of which are hereby incorporated by reference.

Typically, hole blocking layer 130 is at least 5 nm (e.g., at least about 10 nm, at least about 20 nm, at least about 30 nm, at least about 40 nm, or at least about 50 nm) thick and/or at most about 50 nm (e.g., at most about 40 nm, at most about 30 nm, at most about 20 nm, or at most about 10 nm) thick.

In some embodiments, hole blocking layer 130 includes an n-type semiconducting metal oxide (e.g., a titanium oxide, a zinc oxide, a niobium oxide, a tantalum oxide, a tin oxide, a terbium oxide, or a mixture thereof). Without wishing to be bound by theory, it is believed that such an n-type semiconducting metal oxide in hole blocking layer 130 can form ohmic contact between the photoactive material in photoactive layer 140 (which typically is also an n-type semiconducting metal oxide such as titanium oxide). In such embodiments, hole blocking layer 130 can be a non-porous layer. For example, hole blocking layer 130 can be a compact, non-porous titanium oxide layer with a small thickness (e.g., less than about 50 nm). Without wishing to be bound by theory, it is believed that such a compact, non-porous layer can prevent diffusion of contaminants from electrode 120 to photoactive layer 140, thereby minimizing damage caused by such diffusion.

In general, hole blocking layer 130 can be made by the methods described herein or the methods known in the art. For example, when hole blocking layer 130 includes an n-type semiconducting metal oxide (e.g., titanium oxide), the metal oxide can be formed in a sol-gel process. In particular, the metal oxide can be formed by applying a precursor composition containing a precursor (e.g., titanium tetrachloride or titanium tetraisopropoxide) of the metal oxide and an catalyst (e.g., an acid or a base) and sintering the composition at a high temperature (e.g., about 450° C., about 475° C., about 500° C., about 525° C., or about 550° C.) in air.

Photoactive layer 140 generally includes a semiconductor material and a dye associated with the semiconductor material.

In some embodiments, the semiconductor material includes metal oxides, such as n-type semiconducting metal oxides. Examples of suitable n-type semiconducting metal oxides include titanium oxides, zinc oxides, niobium oxides, tantalum oxides, tin oxides, terbium oxides, or a mixture thereof. Other suitable semiconductor materials have been described in, for example, commonly-owned co-pending U.S. Provisional Application No. 61/115,648, and U.S. Application Publication Nos. 2006-0130895 and 2007-0224464, the contents of which are hereby incorporated by reference. In general, the metal oxide in photoactive layer 140 can be the same as or different from the metal oxide in hole blocking layer 130.

In some embodiments, the metal oxide in photoactive layer 140 is in the form of nanoparticles. The nanoparticles can have an average diameter of at least about 20 nm (e.g., at least about 25 nm, at least about 30 nm, or at least about 50 nm) and/or at most about 100 nm (e.g., at most about 80 nm or at most about 60 nm). Preferably, the nanoparticles can have an average diameter between about 25 nm and about 60 nm. Without wishing to be bound by theory, it is believed that nanoparticles with a relatively large average diameter (e.g., larger than about 20 nm) can facilitate filling of solid state hole carrier materials into pores between nanoparticles, thereby improving separation of the charges generated in photovoltaically active layer 140. Without wishing to be bound by theory, it is believed that nanoparticles with a relatively large average diameter (e.g., larger than about 20 nm) can improve electron diffusion due to reduced particle-particle interfaces, which limit electron conduction. Further, without wishing to be bound by theory, it is believed that the nanoparticles in photoactive layer 140 should have an average diameter that is sufficiently small as nanoparticles with an average diameter larger than a certain size (e.g., larger than about 100 nm) may reduce the surface area of the nanoparticles and thereby reducing the short circuit current.

In some embodiments, the metal oxide nanoparticles in photoactive layer 140 can be formed by treating (e.g., heating) a precursor composition containing a precursor of the metal oxide and an acid or a base. Preferably, the metal oxide nanoparticles are formed from the precursor composition containing a base. In certain embodiments, the precursor composition can further include a solvent (e.g., water or an aqueous solvent).

In some embodiments, the base can include an amine, such as tetraalkyl ammonium hydroxide (e.g., tetramethyl ammonium hydroxide (TMAH), tetraethyl ammonium hydroxide, or tetracetyl ammonium hydroxide), triethanolamine, diethylenetriamine, ethylenediamine, trimethylenediamine, or triethylenetetramine. In certain embodiments, the composition contains at least about 0.05 M (e.g., at least about 0.2 M, at least about 0.5 M, or at least about 1 M) and/or at most about 2 M (e.g., at most about 1.5 M, at most about 1 M, or at most about 0.5 M) of the base. Without wishing to be bound by theory, it is believed that different bases can facilitate formation of metal oxide nanoparticles with different shapes. For example, it is believed that tetramethyl ammonium hydroxide facilitates formation of spherical nanoparticles, while tetracetyl ammonium hydroxide facilitates formation of rod/tube like nanoparticles.

Without wishing to be bound by theory, the morphology of metal oxide nanoparticles can be affected by the pH of the precursor composition. For example, when triethanolamine is used as a base, the morphology of TiO₂ nanoparticles can change from cuboidal to ellipsoidal at pH above about 11. As another example, when diethylenetriamine is used as a base, the morphology of TiO₂ nanoparticles can change into ellipsoidal at pH above about 9.5. By contrast, without wishing to be bound by theory, it is believed that when metal oxide nanoparticles are formed in the presence of an acid, the nature and amount of the acid would not affect the morphology of the nanoparticles.

Without wishing to be bound by theory, it is believed that metal oxide nanoparticles with a large length to width aspect ratio could facilitate electron transport, thereby increasing the efficiency of a photovoltaic cell. In some embodiments, metal oxide nanoparticles in photovoltaically active layer 140 has a length to width aspect ratio of at least about 1 (e.g., at least about 5, at least about 10, least about 50, at least about 100, or at least about 500).

In some embodiments, the metal oxide precursor can include a material selected from the group consisting of metal alkoxides, polymeric derivatives of metal alkoxides, metal diketonates, metal salts, and combinations thereof. Exemplary metal alkoxides include titanium alkoxides (e.g., titanium tetraisopropoxide), tungsten alkoxides, zinc alkoxides, or zirconium alkoxides. Exemplary polymeric derivatives of metal alkoxides include poly(n-butyl titanate). Exemplary metal diketonates include titanium oxyacetylacetonate or titanium bis(ethyl acetoacetato)diisopropoxide. Exemplary metal salts include metal halides (e.g., titanium tetrachloride), metal bromides, metal fluorides, metal sulfates, or metal nitrates. In certain embodiments, the precursor composition contains at least about 0.1 M (e.g., at least about 0.2 M, at least about 0.3 M, or at least about 0.5 M) and/or at most about 2 M (e.g., at most about 1 M, at most about 0.7 M, or at most about 0.5 M) of the metal oxide precursor

Methods of forming the precursor composition can vary as desired. In some embodiments, the precursor composition can be formed by adding an aqueous solution of a metal oxide precursor (e.g., titanium tetraisopropoxide) into an aqueous solution of a base (e.g., TMAH).

After the precursor composition is formed, it can undergo thermal treatment to form metal oxide nanoparticles. In some embodiments, the composition can first be heated to an intermediate temperature from about 60° C. to about 100° C. (e.g., about 80° C.) for a sufficient period of time (e.g., from about 7 hours to 9 hours, such as 8 hours) to form a peptized sol. Without wishing to be bound by theory, it is believed that heating the precursor composition at such an intermediate temperature for a period of time can facilitate sol formation. In certain embodiments, the peptized sol can be further heated at a high temperature from about 200° C. to about 250° C. (e.g., about 230° C.) for a sufficient period of time (e.g., from about 10 hours to 14 hours, such as 12 hours) to form metal oxide nanoparticles with a desired average particle size (e.g., an average diameter between about 25 nm and about 60 nm). Without wishing to be bound by theory, it is believed that heating the peptized sol at such a high temperature for a period of time can increase the size of the nanoparticles thus formed to at least about 20 nm and improve the mechanical and electronic properties of these nanoparticles.

After the thermal treatment, the precursor composition can be converted into a printable paste. In some embodiments, the printable paste can be obtained by concentrating the precursor composition containing the metal oxide nanoparticles formed above and then adding an additive (e.g., terpineol and/or ethyl cellulose) to the concentrated composition. The printable paste can then be applied onto another layer in a photovoltaic cell (e.g., an electrode or a hole blocking layer) to form photoactive layer 140. The printable paste can be applied by a liquid-based coating processing discussed in more detail below.

In some embodiments, after the metal oxide nanoparticles are formed in photoactive layer 140, the nanoparticles can be interconnected, for example, by sintering at a high temperature (e.g., about 450° C., about 475° C., about 500° C., about 525° C., or about 550° C.) in air.

In some embodiments, photoactive layer 140 is a porous layer containing metal oxide nanoparticles. In such embodiments, photovoltaically active layer 140 can have a porosity of at least about 40% (e.g., at least about 50% or at least about 60%) and/or at most about 70% (e.g., at most about 60% or at most about 50%). Without wishing to be bound by theory, it is believed that a photoactive layer containing nanoparticles and having a relatively large porosity (e.g., larger than about 40%) can facilitate diffusion of solid state hole carrier materials into pores between nanoparticles, thereby improving separation of the charges generated in the photoactive layer.

In some embodiments, photoactive layer 140 can include a hole carrier material (e.g., a solid state hole carrier material) disposed in the pores. The hole carrier material in photoactive layer 140 can be the same as or different from the hole carrier material in hole carrier layer 150. To obtain a cell in which photoactive layer 140 and hole carrier layer 150 include the same hole carrier material, one can apply an solution containing an excess amount of the hole carrier material and a solvent (e.g., an organic solvent) onto the metal oxide nanoparticles in photoactive layer 140 and dry the solution to dispose the hole carrier material in photoactive layer 140. The excess hole carrier material forms hole carrier layer 150 on photoactive layer 140. To obtain a cell in which photoactive layer 140 and hole carrier layer 150 include different hole carrier materials, one can first apply an solution containing both a suitable amount of a first hole carrier material and a solvent (e.g., an organic solvent) onto the metal oxide nanoparticles and dry the solution to dispose the hole carrier material in photoactive layer 140. Subsequently, one can apply a solution containing both a second hole carrier material and a solvent onto photoactive layer 140 to form hole carrier layer 150.

The semiconductor material in photoactive layer 140 (e.g., interconnected metal oxide nanoparticles) is generally photosensitized by at least a dye (e.g., two or more dyes). The dye facilitates conversion of incident light into electricity to produce the desired photovoltaic effect. It is believed that a dye absorbs incident light, resulting in the excitation of electrons in the dye. The excited electrons are then transferred from the excitation levels of the dye into a conduction band of the semiconductor material. This electron transfer results in an effective separation of charge and the desired photovoltaic effect. Accordingly, the electrons in the conduction band of the semiconductor material are made available to drive an external load.

The dyes suitable for use in photovoltaic cell 100 can have a molar extinction coefficient (c) of at least about 8,000 (e.g., at least about 10,000, at least about 13,000, at least 14,000, at least about 15,000, at least about 18,000, at least about 20,000, at least about 23,000, at least about 25,000, at least about 28,000, and at least about 30,000) at a given wavelength (e.g., λₘₐₓ) within the visible light spectrum. Without wishing to be bound by theory, it is believed that dyes with a high molar extinction coefficient exhibited enhanced light absorption and therefore improves the short circuit current of photovoltaic cell 100.

Examples of suitable dyes include black dyes (e.g., tris(isothiocyanato)-ruthenium (II)-2,2′:6′,2″-terpyridine-4,4′,4″-tricarboxylic acid, tris-tetrabutylammonium salt), orange dyes (e.g., tris(2,2′-bipyridyl-4,4′-dicarboxylato) ruthenium (II) dichloride, purple dyes (e.g., cis-bis(isothiocyanato)bis-(2,2′-bipyridyl-4,4′-dicarboxylato)-ruthenium (II)), red dyes (e.g., an eosin), green dyes (e.g., a merocyanine) and blue dyes (e.g., a cyanine). Examples of black dyes have also been described in commonly-owned co-pending U.S. Application Publication No. 2009-0107552, the contents of which are hereby incorporated by reference. Examples of additional dyes include anthocyanines, porphyrins, phthalocyanines, squarates, and certain metal-containing dyes. Commercially available dyes and dyes reported in the literature include Z907, K19, K51, K60, K68, K77, K78, N3, D 149, and N719. Combinations of dyes can also be used within a given region in photoactive layer 140 so that the given region can include two or more (e.g., two, three, four, five, six, seven) different dyes.

The dye can be sorbed (e.g., chemisorbed and/or physisorbed) onto the semiconductor material. The dye can be selected, for example, based on its ability to absorb photons in a wavelength range of operation (e.g., within the visible spectrum), its ability to produce free electrons (or holes) in a conduction band of the nanoparticles, its effectiveness in complexing with or sorbing to the nanoparticles, and/or its color. In some embodiments, the dye can be sorbed onto the semiconductor material (e.g., a metal oxide) by immersing an intermediate article (e.g., an article containing a substrate, an electrode, a hole blocking layer, and a semiconductor material) into a dye composition for a sufficient period of time (e.g., at least about 12 hours).

In some embodiments, the dye composition can form a monolayer on metal oxide nanoparticles. Without wishing to be bound by theory, it is believed that forming a dye monolayer can prevent direct contact between the metal oxide (e.g., TiO₂) with a conjugated semiconductor polymer in a hole carrier layer, thereby reducing recombination between electrons and holes generated in photoactive layer 140 during use and increasing the open circuit voltage and efficiency of photovoltaic cell 100.

In general, the dye composition includes a solvent, such as an organic solvent. Suitable solvents for the photosensitizing agent composition include alcohols (e.g., primary alcohols, secondary alcohols, or tertiary alcohols). Examples of suitable alcohols include methanol, ethanol, propanol, and 2-methoxy propanol. In some embodiments, the solvent can further include a cyclic ester, such as a γ-butyrolactone. Without wishing to be bound by theory, it is believed that using a solvent (e.g., an alcohol) in which the dye has a relatively poor solubility (e.g., a solubility of at most about 8 mM at room temperature) facilitates formation of a dye monolayer on the metal oxide layer, thereby reducing the recombination between electrons and holes generated in photoactive layer 140 during use. In some embodiments, suitable solvents are those in which the dye has a solubility of at most about 8 mM (e.g., at most about 1 mM) at room temperature.

In some embodiments, the dye composition further includes a proton scavenger. As used herein, the term “proton scavenger” refers to any agent that is capable of binding to a proton. An example of a proton scavenger is a guanidino-alkanoic acid (e.g., 3-guanidino-propionic acid or guanidine-butyric acid). Without wishing to be bound by theory, it is believed that a proton scavenger facilitates removing protons on the metal oxide surface, thereby reducing electron-hole recombination rates and increase the open circuit voltage and efficiency of photovoltaic cell 100.

The thickness of photoactive layer 140 can generally vary as desired. For example, photoactive layer 140 can have a thickness of at least about 500 nm (e.g., at least about 1 micron, at least about 2 microns, or at least about 5 microns) and/or at most about 10 microns (e.g., at most about 8 microns, at most about 6 microns, or at most about 4 microns). Without wishing to be bound by theory, it is believed that photoactive layer 140 having a relative large thickness (e.g., larger than about 2 microns) can have improved light absorption, thereby improving the current density and performance of a photovoltaic cell. Further, without wishing to be bound by theory, it is believed that photoactive layer 140 having a thickness larger than a certain size (e.g., larger than 4 microns) may exhibit reduced charge separation as the thickness can be larger than the diffusion length of the charges generated by the photovoltaic cell during use.

In some embodiments, photoactive layer 140 can be formed by applying a composition containing metal oxide nanoparticles onto a substrate by a liquid-based coating process. The term “liquid-based coating process” mentioned herein refers to a process that uses a liquid-based coating composition. Examples of liquid-based coating compositions include solutions, dispersions, and suspensions (e.g., printable pastes). In some embodiments, the liquid-based coating process can also be used to prepare other layers (e.g., hole blocking layer 130 or hole carrier layer 150) in photovoltaic cell 100.

The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Without wishing to bound by theory, it is believed that the liquid-based coating process can be readily used in a continuous manufacturing process, such as a roll-to-roll process, thereby significantly reducing the cost of preparing a photovoltaic cell. Examples of roll-to-roll processes have been described in, for example, commonly-owned co-pending U.S. Application Publication No. 2005-0263179, the contents of which are hereby incorporated by reference.

The liquid-based coating process can be carried out either at room temperature or at an elevated temperature (e.g., at least about 50° C., at least about 100° C., at least about 200° C., or at least about 300° C.). The temperature can be adjusted depending on various factors, such as the coating process and coating composition used. In some embodiments, nanoparticles in the coated paste can be sintered at a high temperature (e.g., at least about 450° C., at least about 450° C., or at least about 550° C.) to form interconnected nanoparticles.

For example, photovoltaically active layer 140 can be prepared as follows: Metal oxide nanoparticles (e.g., TiO₂ nanoparticles) can be formed by treating (e.g., heating) a composition (e.g., a dispersion) containing a precursor of the metal oxide (e.g., a titanium alkoxide such as titanium tetraisopropoxide) in the presence of an acid or a base. The composition typically includes a solvent (e.g., such as water or an aqueous solvent). After the treatment, the composition can be converted into a printable paste. In some embodiments, the printable paste can be obtained by concentrating the composition containing the metal oxide nanoparticles formed above and then adding an additive (e.g., terpineol and/or ethyl cellulose) to the concentrated composition. The printable paste can then be coated onto another layer in a photovoltaic cell (e.g., an electrode or a hole blocking layer) and then be treated (e.g., by a high temperature sintering process) to form a porous layer containing interconnected metal oxide nanoparticles. Photoactive layer 140 can subsequently be formed by adding a dye composition (e.g., containing a dye, a solvent, and/or a proton scavenger) to the porous layer to sensitize the metal oxide nanoparticles.

Hole carrier layer 150 is generally formed of a material that, at the thickness used in photovoltaic cell 100, transports holes to electrode 160 and substantially blocks the transport of electrons to electrode 160. Examples of materials from which layer 150 can be formed include spiro-MeO-TAD, triaryl amines, polythiophenes (e.g., P3HT or PEDOT doped with poly(styrene-sulfonate)), polyanilines, polycarbazoles, polyvinylcarbazoles, polyphenylenes, polyphenylvinylenes, polysilanes, polythienylenevinylenes, polyisothianaphthanenes, and copolymers thereof. In some embodiments, hole carrier layer 150 can include combinations of hole carrier materials.

In general, the thickness of hole carrier layer 150 (i.e., the distance between the surface of hole carrier layer 150 in contact with photoactive layer 140 and the surface of electrode 160 in contact with hole carrier layer 150) can vary as desired. Typically, the thickness of hole carrier layer 150 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 150 is from about 0.01 micron to about 0.5 micron.

Electrode 160 is generally formed of an electrically conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel, or 430 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., P3HT or doped poly(3,4-ethylenedioxythiophene) (doped PEDOT)), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some embodiments, electrode 160 is formed of a combination of electrically conductive materials.

In some embodiments, electrode 160 can include a mesh or grid electrode. Examples of mesh or grid electrodes are described in commonly-owned co-pending U.S. Patent Application Publication Nos. 2004-0187911 and 2006-0090791, the entire contents of which are hereby incorporated by reference. In certain embodiments, electrode 160 includes a mesh or grid electrode disposed on a electrically conductive layer containing an electrically conducting or semiconducting polymer (e.g., doped PEDOT).

Electrode 160 can be either transparent or non-transparent. In general, at least one of electrodes 120 and 160 is transparent.

In some embodiments, when a layer (e.g., one of layers 130-160) includes inorganic nanoparticles, the liquid-based coating process can be carried out by (1) mixing the nanoparticles with a solvent (e.g., an aqueous solvent or an anhydrous alcohol) to form a dispersion, (2) coating the dispersion onto a substrate, and (3) drying the coated dispersion. In certain embodiments, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a photoactive layer, (3) hydrolyzing the dispersion to form an inorganic metal oxide nanoparticles layer (e.g., a titanium oxide nanoparticles layer), and (4) drying the inorganic metal oxide layer. In certain embodiments, the liquid-based coating process can include a sol-gel process.

In general, the liquid-based coating process used to prepare a layer containing an organic material can be the same as or different from that used to prepare a layer containing an inorganic material. In some embodiments, when a layer (e.g., one of layers 130-160) includes an organic material, the liquid-based coating process can be carried out by mixing the organic material with a solvent (e.g., an organic solvent) to form a solution or a dispersion, coating the solution or dispersion on a substrate, and drying the coated solution or dispersion.

Substrate 170 can be identical to or different from substrate 110. In some embodiments, substrate 170 can be formed of one or more suitable polymers, such as the polymers used in substrate 110 described above. In some embodiments, substrate 170 is an insulating layer protecting photovoltaic cell 100 from damage caused by the environment. In some embodiments, substrate 170 is optional and can be omitted from photovoltaic cell 100.

During operation, in response to illumination by radiation (e.g., in the solar spectrum), photovoltaic cell 100 undergoes cycles of excitation, oxidation, and reduction that produce a flow of electrons across the external load. Specifically, incident light passes through at least one of substrates 110 and 170 and excites the dye in photoactive layer 140. The excited dye then injects electrons into the conduction band of the semiconductor material in photoactive layer 140, which leaves the dye oxidized. The injected electrons flow through the semiconductor material and hole blocking layer 130, to electrode 120, then to the external load. After flowing through the external load, the electrons flow to electrode 160, hole carrier layer 150, and photoactive layer 140, where the electrons reduce the oxidized dye molecules back to their neutral state. This cycle of excitation, oxidation, and reduction is repeated to provide continuous electrical energy to the external load.

While certain embodiments have been disclosed, other embodiments are also possible.

In some embodiments, photovoltaic cell 100 includes a cathode as a bottom electrode and an anode as a top electrode. In some embodiments, photovoltaic cell 100 can include an anode as a bottom electrode and a cathode as a top electrode.

In some embodiments, photovoltaic cell 100 can include the layers shown in FIG. 1 in a reverse order. In other words, photovoltaic cell 100 can include these layers from the bottom to the top in the following sequence: an optional substrate 170, an electrode 160, a hole carrier layer 150, a photoactive layer 140, an optional hole blocking layer 130, an electrode 120, and an optional substrate 110.

While photovoltaic cells have been described above, in some embodiments, the compositions and methods described herein can be used in tandem photovoltaic cells. Examples of tandem photovoltaic cells have been described in, for example, commonly-owned co-pending U.S. Application Publication Nos. 2007-0181179 and 2007-0246094, the entire contents of which are hereby incorporated by reference.

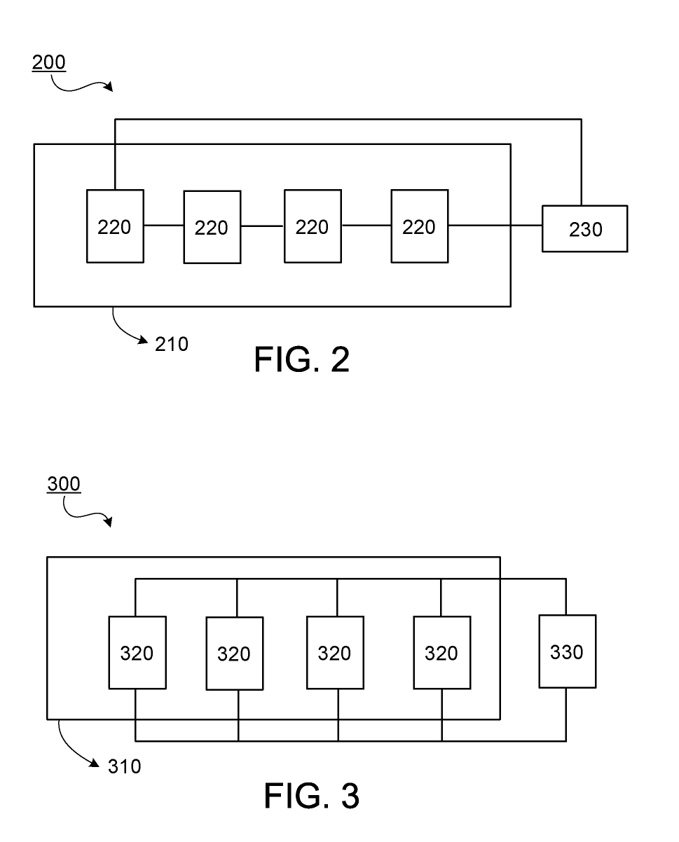

In some embodiments, multiple photovoltaic cells can be electrically connected to form a photovoltaic system. As an example, FIG. 2 is a schematic of a photovoltaic system 200 having a module 210 containing photovoltaic cells 220. Cells 220 are electrically connected in series, and system 200 is electrically connected to a load 230. As another example, FIG. 3 is a schematic of a photovoltaic system 300 having a module 310 that contains photovoltaic cells 320. Cells 320 are electrically connected in parallel, and system 300 is electrically connected to a load 330. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

While photovoltaic cells have been described above, in some embodiments, the compositions and methods described herein can be used in other electronic devices and systems. For example, they can be used in field effect transistors, photodetectors (e.g., IR detectors), photovoltaic detectors, imaging devices (e.g., RGB imaging devices for cameras or medical imaging systems), light emitting diodes (LEDs) (e.g., organic LEDs or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

The following examples are illustrative and not intended to be limiting.

### EXAMPLE 1

### Effect of a Titanium Layer on Performance of Stainless Steel Foil Based Solid State Dye Sensitized Solar Cell (SSDSSC)

A first SSDSSC (i.e., cell 1) having a stainless steel bottom electrode without a titanium layer was prepared as follows: A commercially available SS430 stainless steel foil (100 microns thick) was cut into a desired size and cleaned by sequential ultrasonicating in a 2% detergent solution in DI water, 2× DI water, isopropanol, and acetone. The foil was subsequently air dried followed by drying in a 150° C. oven for 15 minutes. A 0.1 M titanium (IV) tetra(isopropoxide) solution in ethanol was spun coated on the stainless steel foil and then sintered at 450° C. for 5 minutes to form a 50 nm thick compact, non-porous TiO₂ layer as a hole blocking layer. A 2-5 micron thick film containing colloidal titanium oxide (Dyesol, Australia) with an average particle size of 20 nm was formed on the hole blocking layer by using blade coating. The film was subsequently sintered at 500° C. for 30 minutes followed by cooling to about 100° C. The device thus obtained was placed in a dye solution containing 0.3 mM D149 and a 1:1 acetonitrile:t-butanol solvent mixture. After the device was soaked for 24 hours, it was removed from the dye solution, rinsed with acetonitrile, and air dried for 5 minutes to form a porous photoactive layer containing dye sensitized TiO₂ nanoparticles. A solution containing 5% spiro-MeO-TAD doped with 0.08% of a Sb complex (i.e., [N(p-C₆H₄Br)₃][SbCl₆]) in chlorobenzene was spun cast onto the photoactive layer to form a hole carrier layer containing spiro-MeO-TAD and to fill the pores in photoactive layer 140 with spiro-MeO-TAD. A highly conducting PEDOT:PSS layer was then deposited on top of the hole carrier layer by spin coating from an 1% aqueous PEDOT:PSS solution. A gold grid with more than 90% open area and a thickness of 60 nm was then deposited on the PEDOT layer using vacuum evaporation process to form a top electrode.

A second SSDSSC (i.e., cell 2) having a stainless steel bottom electrode with a titanium layer was prepared by the same procedure described above except that a titanium layer with a thickness of 3 microns was coated on the stainless steel foil before the TiO₂ hole blocking layer was formed.

A third SSDSSC (i.e., cell 3) was prepared in the same manner as cell 2 except that cell 3 did not include the TiO₂ hole blocking layer.

A fourth SSDSSC (i.e., cell 4) was prepared in the same manner as cell 3 except that its size is about a half of that of cell 3.

The performance of cells 1-4 was measured at simulated 1 sun light under AM 1.5 conditions. The test results are summarized in Table 1 below.

TABLE 1

| | | | Jsc | | Efficiency |
|---|---|---|---|---|---|
| Cell ID | Size (cm²) | Voc (V) | (mA/cm²) | Fill factor | (%) |
| 1 | 1 | 0.308 | 0.642 | 25.2 | 0.05 |
| 2 | 0.34 | 0.808 | 2.363 | 69.7 | 1.33 |
| 3 | 0.34 | 0.696 | 3.596 | 66.6 | 1.67 |
| 4 | 0.16 | 0.655 | 3.722 | 74 | 1.8 |

As shown in Table 1, the SSDSSC without a titanium layer coated on a stainless steel bottom electrode (i.e., cell 1) exhibited very low short-circuit current and therefore very low efficiency. On the other hand other, the SSDSSCs with a titanium layer coated on a stainless steel bottom electrode (i.e., cells 2-4) all exhibited relatively high short-circuit current and efficiency.

### EXAMPLE 2

### Comparison Between SSDSSCs Having a Titanium Foil and SSDSSCs Having a Stainless Steel Coated with a Titanium Layer

Six SSDSSCs (i.e., cells 5-10) with different bottom electrodes, hole blocking layers (HBLs), dyes, and hole carrier layers (HCLs) were prepared following the general procedure described in Example 1. In cells 5, 8, and 10, the hole blocking layer was formed by spray coating a titanium tetra(isoproxide) solution in ethanol on the foil, which was then sintered at 450° C. to form a compact, non-porous TiO₂ layer. In cell 6, the hole blocking layer was formed by forming TiO₂ particles in a sol-gel process, which were then applied on the foil and sintered at 450° C. to form a compact, non-porous TiO₂ layer. In cell 7 and 9, no hole blocking layer was formed. In addition, cells 5-8 were soaked in a K51 dye solution overnight and Cells 9-10 were soaked in a D149 dye solution for 2 hours.

The performance of cells 5-10 was measured at simulated 1 sun light under AM 1.5 conditions. The composition of cells 5-10 and their test results are summarized in Table 2 below.

TABLE 2

| Cell | Bottom | | | | Size | Jsc | Voc | Efficiency |
|---|---|---|---|---|---|---|---|---|
| ID | Electrode | HBL | Dye | HCL | (cm²) | (mA/cm²) | (V) | (%) |
| 5 | Ti foil | Spray | K51 | spiro-MeO-TAD | 0.16 | 3.74 | 0.690 | 1.88 |
| | (18 | coating | | doped with [N(p- | | | | |
| | microns) | | | C₆H₄Br)₃][SbCl₆] | | | | |
| 6 | Ti foil | Sol-gel | K51 | spiro-MeO-TAD | 0.16 | 2.92 | 0.790 | 1.68 |
| | (18 | | | doped with [N(p- | | | | |
| | microns) | | | C₆H₄Br)₃][SbCl₆] | | | | |
| 7 | SS430 + | None | K51 | spiro-MeO-TAD | 0.16 | 2.1 | 0.705 | 1.12 |
| | 3-micron | | | | | | | |
| | Ti | | | | | | | |
| 8 | SS430 + | Spray | K51 | spiro-MeO-TAD | 0.16 | 1.52 | 0.742 | 0.85 |
| | 3-micron | coating | | | | | | |
| | Ti | | | | | | | |
| 9 | SS430 + | None | D149 | spiro-MeO-TAD | 0.16 | 2.55 | 0.738 | 1.57 |
| | 3-micron | | | | | | | |
| | Ti | | | | | | | |
| 10 | SS430 + | Spray | D149 | spiro-MeO-TAD | 0.16 | 2.36 | 0.792 | 1.51 |
| | 3-micron | coating | | | | | | |
| | Ti | | | | | | | |

As shown in Table 2, SSDSSCs with a titanium layer coated on a stainless steel bottom electrode (i.e., cells 7-10) exhibited somewhat lower efficiencies than those exhibited by SSDSSCs with a titanium foil as a bottom electrode (cells 5-6) due to the presence of the Sb complex, which is believed to make spiro-MeO-TAD more electrically conductive. When the Sb complex is removed from spiro-MeO-TAD in cells 5-6, the efficiencies of the cells thus formed are expected to be similar to those of cells 7-10. Because cells 7-10 are much less costly to manufacture than cells 5-6 as they contain a much less expensive bottom electrode, the results above show titanium can also be used as a coating on a stainless steel foil in a bottom electrode to form an inexpensive SSDSSC with a relatively high efficiency.

### EXAMPLE 3

### SSDSSC Containing a Stainless Steel Foil Coated with TiN as a Bottom Electrode

A SSDSSC containing a SS430 stainless steel foil coated with TiN as a bottom electrode was prepared following the procedure described in Example 1. The performance of this was measured at simulated 1 sun light under AM 1.5 conditions. The results showed that this cell exhibited a Jsc of 3 mA/cm², a Voc of 800 mV, a fill factor of 0.49, and an efficiency of 1.18%. In other words, the results show that the electrically conductive ceramic material TiN can also be used as a coating on a stainless steel foil in a bottom electrode to form an inexpensive SSDSSC with a relatively high efficiency.

Other embodiments are in the claims.

What is claimed is:

1. An article, comprising:
a first electrode comprising first and second layers, the first layer comprising a first metal capable of forming an n-type semiconducting metal oxide and the second layer comprising a second metal different from the first metal;
a photoactive layer comprising a first metal oxide and a dye, the first metal oxide being an n-type semiconducting metal oxide, the first layer being between the second layer and the photoactive layer; and
a second electrode, the photoactive layer being between the first layer and the second electrode;
wherein the article is configured as a solid state dye sensitized photovoltaic cell.

2. The article of claim 1, wherein the first metal comprises titanium, tantalum, niobium, zinc, tin, or an alloy thereof.

3. The article of claim 1, wherein the first layer has a thickness of between about 100 nm and about 5 microns.

4. The article of claim 1, wherein the first layer has a thickness of between about 500 nm and about 2 microns.

5. The article of claim 1, wherein the second metal comprises iron, aluminum, copper, nickel, chromium, vanadium, manganese, tungsten, molybdenum, or an alloy thereof.

6. The article of claim 1, wherein the second layer has a thickness of between about 5 microns and about 500 microns.

7. The article of claim 1, wherein the second layer comprises a metal foil.

8. The article of claim 1, wherein the first metal oxide comprises a titanium oxide, a zinc oxide, a niobium oxide, a tantalum oxide, a tin oxide, a terbium oxide, or a mixture thereof.

9. The article of claim 1, wherein the first metal oxide comprises nanoparticles having an average particle diameter of between 20 nm and 100 nm.

10. The article of claim 1, wherein the photoactive layer is a porous layer.

11. The article of claim 1, wherein the photoactive layer comprises a plurality of pores and a hole carrier material in at least some of the plurality of pores.

12. The article of claim 1, further comprising a hole blocking layer between the first layer and the photoactive layer.

13. The article of claim 12, wherein the hole blocking layer comprises a second metal oxide.

14. The article of claim 13, wherein the second metal oxide comprises an n-type semiconducting metal oxide.

15. The article of claim 13, wherein the second metal oxide comprises a titanium oxide, a zinc oxide, a niobium oxide, a tantalum oxide, a tin oxide, a terbium oxide, or a mixture thereof.

16. The article of claim 12, wherein the hole blocking layer has a thickness of between 5 nm and 50 nm.

17. The article of claim 12, wherein the hole blocking layer is a non-porous layer.

18. The article of claim 1, further comprising a hole carrier layer between the photoactive layer and the second electrode.

19. The article of claim 18, wherein the hole carrier layer comprises a material selected from the group consisting of spiro-MeO-TAD, triaryl amines, polythiophenes, polyanilines, polycarbazoles, polyvinylcarbazoles, polyphenylenes, polyphenylvinylenes, polysilanes, polythienylenevinylenes, polyisothianaphthanenes, and copolymers or mixtures thereof.

20. The article of claim 19, wherein the hole carrier layer comprises poly(3-hexylthiophene) or poly(3,4-ethylenedioxythiophene).

21. The article of claim 18, wherein the hole carrier layer comprises a first hole carrier material, and the photoactive layer comprises a plurality of pores and a second hole carrier material in at least some of the plurality of pores.

22. The article of claim 21, wherein the first hole carrier material is the same as the second hole carrier material.

23. The article of claim 1, wherein the second electrode is transparent.

24. The article of claim 1, wherein the second electrode comprises a mesh or grid electrode.

25. An article, comprising:
a first electrode comprising first and second layers, the first layer comprising an electrically conductive material that does not form an electrically insulating metal oxide or a p-type semiconducting metal oxide upon heating at a temperature of about 500° C. in air, and the second layer comprising a metal;
a photoactive layer comprising a first metal oxide and a dye, the first metal oxide being an n-type semiconducting metal oxide, the first layer being between the second layer and the photoactive layer; and
a second electrode, the photoactive layer being between the first layer and the second electrode;
wherein the article is configured as a solid state dye sensitized photovoltaic cell.

26. The article of claim 25, wherein the electrically conductive material does not form a metal oxide upon heating at a temperature of about 500° C. in air.

27. The article of claim 25, wherein the electrically conductive material comprises a ceramic material containing titanium, tantalum, niobium, zinc, or tin.

28. The article of claim 27, wherein the ceramic material comprises titanium nitride, titanium carbon nitride, titanium aluminum nitride, titanium aluminum carbon nitride, tantalum nitride, niobium nitride, zinc nitride, or tin nitride.

29. The article of claim 28, wherein the ceramic material comprises titanium nitride.

30. The article of claim 25, wherein the first layer comprises titanium or titanium nitride.

31. An article, comprising:
a first electrode comprising first and second layers, the first layer comprising an electrically conductive material, the electrically conductive material comprising a first metal or a ceramic material, the first metal being selected from the group consisting of titanium, tantalum, niobium, zinc, tin, and an alloy thereof, the ceramic material comprising titanium, tantalum, niobium, zinc, or tin, and the second layer comprising a second metal different from the first metal;
a photoactive layer comprising a titanium oxide and a dye, the photoactive layer comprising a plurality of pores and a hole carrier material in at least some of the plurality of pores, and the first layer being between the second layer and the photoactive layer;
a hole carrier layer, the hole carrier layer comprising the hole carrier material and the photoactive layer being between the first layer and the hole carrier layer, and
a second electrode, the hole carrier layer being between the photoactive layer and the second electrode;
wherein the article is configured as a solid state dye sensitized photovoltaic cell.

32. The article of claim 31, wherein the first layer comprises titanium or titanium nitride.
